(19) United States
(12) Patent Application Publication
(10) Pub. No.: US 2026/0291498 A1
(43) Pub. Date: Sep. 24, 2026

(54) GATE DRIVER CIRCUIT AND SWITCHING CIRCUIT

(71) Applicant: ROHM CO., LTD., Kyoto (JP)

(72) Inventor: Hisashi SUGIE, Kyoto (JP)

(21) Appl. No.: 19/569,138

(22) Filed: Mar. 17, 2026

(30) Foreign Application Priority Data
Mar. 24, 2025 (JP) 2025-049027

(51) Int. Cl. H03K 17/687; H02M 1/088; H02M 7/5387

(52) U.S. Cl. CPC H03K 17/6871; H02M 1/088; H02M 7/53871; H03K 2217/0063; H03K 2217/0072

(57) ABSTRACT

A gate driver circuit for driving a power transistor includes a turn-on circuit that sources a turn-on current to a gate of the power transistor during a turn-on period, a turn-off circuit that sinks a turn-off current from the gate during a turn-off period, and a control circuit that controls the turn-on and turn-off circuits. The turn-on circuit or the turn-off circuit includes a current source circuit that switches an amount of the turn-on current or the turn-off current. The current source circuit includes first and second switching current sources. The first switching current source includes first transistors and sources or sinks a first switching current to or from the gate. The second switching current source includes second transistors and sources or sinks a second switching current to or from the gate. The control circuit individually controls on/off states of the first and second transistors.

### CROSS-REFERENCE TO RELATED APPLICATION

The present invention claims priority under 35 U.S.C. § 119 to Japanese Patent Application No. 2025-049027, filed on Mar. 24, 2025, the entire contents of which are incorporated herein by reference.

### TECHNICAL FIELD

The present disclosure relates to a gate driver circuit and a switching circuit.

### BACKGROUND

In the related art, a half-bridge circuit, an H-bridge circuit, and a three-phase bridge circuit (hereinafter, collectively referred to sometimes as a “switching circuit”) using a power transistor have been used in a motor driver circuit, a DC/DC converter, a power conversion device, and the like.

For example, in the related art, there is disclosed a drive circuit that drives a bridge circuit including a high-side transistor and a low-side transistor. The drive circuit includes a high-side driver circuit that drives the high-side transistor and a low-side driver circuit that drives the low-side driver. In the related art, for example, the high-side driver circuit includes a current DAC (D/A converter) that generates an output current, and the high-side transistor is turned on by such an output current.

### BRIEF DESCRIPTION OF DRAWINGS

The accompanying drawings, which are incorporated in and constitute a part of the specification, illustrate embodiments of the present disclosure.

FIG. 1 is a block diagram of a switching circuit according to a first embodiment.

FIG. 2 is a block diagram of a high-side driver according to the first embodiment.

FIG. 3 is a circuit diagram showing a first switching current source and a second switching current source of a turn-on circuit according to the first embodiment, and a third switching current source and a fourth switching current source of a turn-off circuit according to the first embodiment.

FIG. 4 is a diagram illustrating a configuration of a first transistor according to the first embodiment.

FIG. 5 is a diagram illustrating a configuration of a second transistor according to the first embodiment.

FIG. 6 is a circuit diagram showing a first base current source and a second base current source of the turn-on circuit according to the first embodiment, and a third base current source and a fourth base current source of the turn-off circuit according to the first embodiment.

FIG. 7 is a block diagram illustrating configurations of a level shifter block and a high-side selector according to the first embodiment.

FIG. 8 is a waveform diagram showing an operation example of a gate driver circuit according to the first embodiment.

FIG. 9 is a waveform diagram showing an operation example of the turn-on circuit according to the first embodiment.

FIG. 10 is a block diagram of a gate driver circuit according to a comparative technique.

FIG. 11 is a block diagram of a high-side driver according to the comparative technique.

FIG. 12 is a diagram illustrating a configuration of transistors in a switching current source according to the comparative technique.

FIG. 13 is a reference diagram showing an example of a layout of MOS transistors of two different sizes.

FIG. 14 is a block diagram of a control circuit according to a second embodiment.

FIG. 15 is a block diagram of a motor drive device according to an application example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### (Overview)

An overview of some exemplary embodiments of the present disclosure will be described. This overview presents, in a simplified form, some concepts of one or more embodiments, as a prologue to the detailed description which will be presented later, and for the purpose of basic understanding of the embodiments, but it is not intended to limit the scope of the invention or the disclosure. This overview is not a comprehensive overview of all possible embodiments, and it is intended to neither identify key elements of all embodiments nor delineate the scope of some or all aspects. For the sake of convenience in description, “an embodiment” may be used to refer to one embodiment (example or modification) or a plurality of embodiments (examples or modifications) disclosed herein.

A gate driver circuit according to one embodiment drives a power transistor. The gate driver circuit includes: a turn-on circuit that sources a turn-on current to a gate of the power transistor during a turn-on period of the power transistor; a turn-off circuit that sinks a turn-off current from the gate of the power transistor during a turn-off period of the power transistor; and a control circuit that controls the turn-on circuit and the turn-off circuit. The turn-on circuit or the turn-off circuit has a current source circuit configured to be capable of switching an amount of the turn-on current or the turn-off current. The current source circuit has a first switching current source and a second switching current source. The first switching current source includes a plurality of first transistors connected in parallel and is configured to source or sink a first switching current to or from the gate, the first switching current corresponding to a first transistor, which is turned on, among the plurality of first transistors. The second switching current source includes a plurality of second transistors connected in parallel and is configured to source or sink a second switching current to or from the gate, the second switching current corresponding to a second transistor, which is turned on, among the plurality of second transistors. The first transistor is constituted with a MOS transistor having a first gain. The second transistor is constituted with a MOS transistor having a second gain greater than the first gain. The control circuit individually controls on/off states of the plurality of first transistors or on/off states of the plurality of second transistors.

With this configuration, the control circuit may achieve a necessary turn-on current (or turn-off current) by individually switching the on/off state of the first transistor or the second transistor. In this case, the first transistor and the second transistor are constituted with MOS transistors having two types of gain. This makes it possible to reduce a transistor area compared with a case in which all transistors are constituted with MOS transistors having a single type of gain. Thus, it is possible to drive the power transistor with transistors having a smaller area.

In one embodiment, each of the first transistor and the second transistor may be configured to operate in a saturation region.

In one embodiment, the control circuit may be configured to be capable of switching a mode between a first mode in which the on/off states of the plurality of first transistors are individually controlled, and a second mode in which the on/off states of the plurality of second transistors are individually controlled.

In one embodiment, a non-zero minimum value of the second switching current may be between a non-zero minimum value of the first switching current and a maximum value of the first switching current. The maximum value of the second switching current may be higher than the maximum value of the first switching current.

In one embodiment, the control circuit may generate a multi-bit control signal and a single-bit mode signal indicating the mode of the control circuit. Each bit of the control signal may be associated with a respective one of the plurality of first transistors and a respective one of the plurality of second transistors. Of the first transistor and the second transistor, the on/off state of a corresponding transistor in a mode indicated by the mode signal may be switched, and the remaining transistor may be turned off. Of the plurality of first transistors and the plurality of second transistors, the on/off states of a plurality of corresponding transistors in a switchable state may be individually switched in response to the control signal.

In one embodiment, the gate driver circuit may further include: a plurality of control level shifters, a mode level shifter, and a selector. Each of the plurality of control level shifters may level-shift a signal of a corresponding bit of the control signal. The mode level shifter may level-shift the mode signal. Based on the level-shifted control signal from the control level shifter and the level-shifted mode signal from the mode level shifter, the selector may generate a gate signal for controlling the on/off state of one of the first transistor and the second transistor in a mode indicated by the mode signal, and a gate signal for turning off the remaining transistor.

In one embodiment, the current source circuit may further include a base current source that generates a constant amount of base current in the same direction as those of the first switching current and the second switching current.

In one embodiment, the control circuit may turn on at least one of the plurality of first transistors and turns off all of the plurality of second transistors during a first period, turn off all of the plurality of first transistors and the plurality of second transistors during a second period following the first period, and turn off all of the plurality of first transistors and turns on at least one of the plurality of second transistors during a third period following the second period. An amount of the second switching current during the third period may be greater than that of the first switching current during the first period.

In one embodiment, the base current source may include a first base current source that generates a first base current, and a second base current source that generates a second base current. The first base current source may include a third transistor configured as a MOS transistor having the first gain. The second base current source may include a fourth transistor configured as a MOS transistor having the second gain.

In one embodiment, the control circuit may simultaneously and individually control the on/off states of the plurality of first transistors and the on/off states of the plurality of second transistors.

In one embodiment, a size of the MOS transistor constituting the second transistor may be larger than that of the MOS transistor constituting the first transistor.

In one embodiment, the number of first transistors may be m (m is an integer of 2 or greater). The number of second transistors may be n (n is an integer of 2 or greater). An α-th (α is an integer from 1 to m) first transistor of the plurality of first transistors may be constituted with 2^{α-1} MOS transistors having the first gain. A β-th (β is an integer from 1 to n) second transistor of the plurality of second transistors may constituted with 2^{β-1} MOS transistors having the second gain.

A switching circuit according to one embodiment is provided with: a bridge circuit including a high-side transistor and a low-side transistor; and the above-described gate driver circuit. The gate driver circuit is configured to drive the high-side transistor or the low-side transistor as a power transistor.

### Embodiments

Preferred embodiments will now be described with reference to the drawings. Like or equivalent components, members, and processes illustrated in each drawing are given like reference numerals and a repeated description thereof will be properly omitted. Further, the embodiments are presented by way of example only and are not intended to limit the present disclosure and invention, and any features or combination thereof described in the embodiments may not necessarily be essential to the present disclosure and invention.

In this specification, the expression “a member A is connected to a member B” includes not only a case where the member A and the member B are physically directly connected to each other, but also a case where the member A and the member B are indirectly connected to each other via any other member that does not substantially affect an electrical connection state between the members A and B or does not impair functions and effects achieved by combinations of the members A and B.

Similarly, the expression “a member C is connected (installed) between a member A and a member B” includes not only a case where the member A and the member C or the member B and the member C are directly connected to each other, but also a case where the member A and the member C or the member B and the member C are indirectly connected to each other via any other member that does not substantially affect an electrical connection state between the members A and C or the members B and C or does not impair functions and effects achieved by combinations of the members A and C or the members B and C.

Further, in the present disclosure, symbols attached to electrical signals such as voltage signals and current signals, or circuit elements such as resistors, capacitors, and inductors, represent respective voltage values, current values, or circuit constants (resistance, capacitance, and inductance) as necessary.

Further, in the present disclosure, the term “integrated” includes a case where all of constituent elements of a circuit are formed on a semiconductor substrate and a case where main constituent elements of the circuit are integrated, and some resistors, capacitors, and the like may be provided outside the semiconductor substrate for adjusting circuit constants.

### First Embodiment

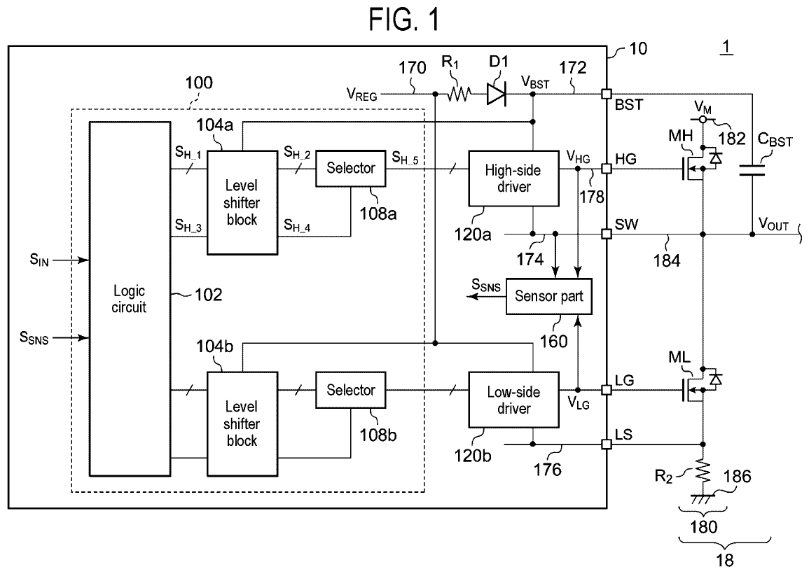

FIG. 1 is a block diagram of a switching circuit 1 according to a first embodiment. The switching circuit 1 according to this embodiment includes a gate driver circuit 10 and a peripheral circuit 18. The gate driver circuit 10 and the peripheral circuit 18 are connected to each other via various pins (for example, a bootstrap pin BST, a high-side gate pin HG, a switching pin SW, a low-side gate pin LG, and a low-side source pin LS) of the gate driver circuit 10.

The peripheral circuit 18 includes a half-bridge circuit 180 and a bootstrap capacitor CBST. The half-bridge circuit 180 includes a high-side transistor MH, a low-side transistor ML, and a resistor R₂. Each of the high-side transistor MH and the low-side transistor ML is a power transistor. In this embodiment, each of the high-side transistor MH and the low-side transistor ML is configured as an N-channel metal oxide semiconductor (MOS) transistor.

The high-side transistor MH is provided between an input line 182 supplied with an input voltage V_{M} and an output line 184 supplied with an output voltage V_{OUT}. A gate of the high-side transistor MH is connected to the high-side gate pin HG. The low-side transistor ML is provided between the output line 184 and a ground line 186. A source of the low-side transistor ML is connected to the low-side source pin LS. A gate of the low-side transistor ML is connected to the low-side gate pin LG. The resistor R₂ is provided between the low-side transistor ML and the ground line 186. The bootstrap capacitor CBST is provided between the bootstrap pin BST and the output line 184.

The gate driver circuit 10 is configured to drive the high-side transistor MH and the low-side transistor MH. The gate driver circuit 10 according to this embodiment is a functional integrated circuit (IC) integrated on a single semiconductor substrate. The gate driver circuit 10 mainly includes a control circuit 100, a high-side driver 120a, a low-side driver 120b, a sensor part 160, a resistor R₁, and a diode D1. The gate driver circuit 10 according to this embodiment further includes a power supply line 170 supplied with a constant voltage VREG, a bootstrap line 172 connected to the bootstrap pin BST, a switching line 174 connected to the switching pin SW, a low-side source line 176 connected to the low-side source pin LS, and a high-side gate line 178 connected to the high-side gate pin HG.

The control circuit 100 controls the high-side driver 120a and the low-side driver 120b. The control circuit 100 according to this embodiment controls these drivers based on an input signal S_{IN} and a sensor signal S_{SNS}. A specific configuration of the control circuit 100 will be described in detail after explaining configurations of the high-side driver 120a and the low-side driver 120b.

The sensor part 160 detects various voltages and generates the sensor signal S_{SNS}. The sensor signal S_{SNS} may include, for example, signals indicating a result of comparing the gate-source voltage V_{GS(H)} of the high-side transistor MH with a first threshold voltage Vₜₕ₁, a result of comparing the output voltage V_{OUT} with a second threshold voltage Vₜₕ₂, and a result of comparing a difference between the input voltage V_{M} and the output voltage V_{OUT} with a third threshold voltage Vₜₕ₃. The generated sensor signal S_{SNS} is transmitted to a logic circuit 102.

The high-side driver 120a is provided between the bootstrap line 172 and the switching line 174. When turning on the high-side transistor MH, the high-side driver 120a sources a turn-on current to the gate of the high-side transistor MH. This charges a capacitance of the gate of the high-side transistor MH, increasing a gate-source voltage of the high-side transistor MH. Further, when turning off the high-side transistor MH, the high-side driver 120a sinks a turn-off current from the gate of the high-side transistor MH. This discharges the capacitance of the gate of the high-side transistor MH, decreasing the gate-source voltage of the high-side transistor MH.

The low-side driver 120b is provided between the power supply line 170 and the low-side source line 176. When turning on the low-side transistor ML, the low-side driver 120b sources a turn-on current to the gate of the low-side transistor ML. This charges the capacitance of the gate of the low-side transistor ML, increasing a gate-source voltage of the low-side transistor ML. Further, when turning off the low-side transistor ML, the low-side driver 120b sinks a turn-off current from the gate of the low-side transistor ML. This discharges the capacitance of the gate of the low-side transistor ML, decreasing the gate-source voltage of the low-side transistor ML.

The resistor R₁ and the diode D1, together with the bootstrap capacitor CBST, constitute a bootstrap circuit. One end of the resistor R₁ is connected to the power supply line 170, and the other end of the resistor R₁ is connected to an anode of the diode D1. A cathode of the diode D1 is connected to the bootstrap line 172.

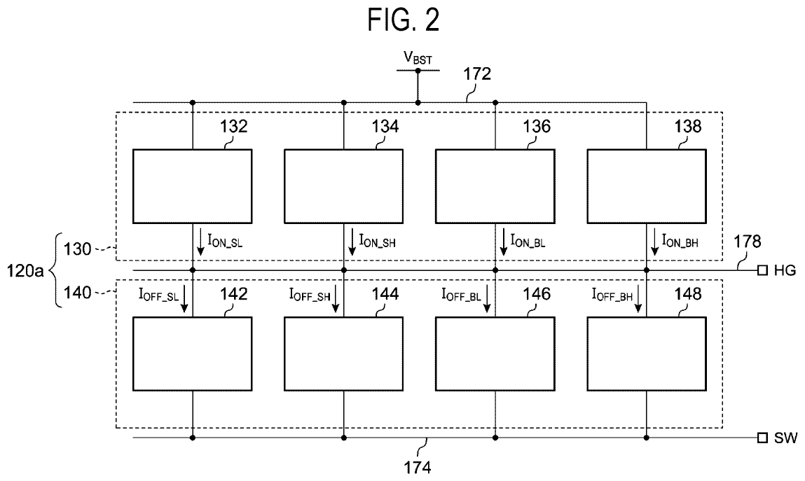

FIG. 2 is a block diagram of the high-side driver 120a according to this embodiment. The high-side driver 120a includes a turn-on circuit 130 and a turn-off circuit 140. The turn-on circuit 130 sources a turn-on current I_{ON} to the gate of the high-side transistor MH during the turn-on period of the high-side transistor MH. The turn-off circuit 140 sinks a turn-off current I_{OFF} from the gate of the high-side transistor MH during the turn-off period of the high-side transistor MH. Further, the low-side driver 120b may have a same configuration as that of the high-side driver 120a.

The turn-on circuit 130 is constituted with a current source circuit configured to be capable of switching an amount of turn-on current I_{ON}. The turn-on circuit 130 according to this embodiment includes a first switching current source 132, a second switching current source 134, a first base current source 136, and a second base current source 138. The first switching current source 132, the second switching current source 134, the first base current source 136, and the second base current source 138 are connected in parallel between the bootstrap line 172 and the high-side gate line 178.

Each of the first switching current source 132 and the second switching current source 134 is configured to be capable of switching an amount of current, and is a current DAC in this embodiment. The first switching current source 132 and the second switching current source 134 respectively source a first switching current I_{ON_SL} and a second switching current I_{ON_SH} to the high-side gate pin HG.

The first base current source 136 and the second base current source 138 generate constant base currents in the same direction as those of the first switching current I_{ON_SL} and the second switching current I_{ON_SH}, respectively. Specifically, the first base current source 136 sources a first base current I_{ON_BL} to the high-side gate pin HG, and the second base current source 138 sources a second base current I_{ON_BH} to the high-side gate pin HG. The sum of the currents sourced by these current sources is the turn-on current I_{ON}. That is, I_{ON}=I_{ON_SL}+I_{ON_SH}+I_{ON_BL}+I_{ON_BH}.

The turn-off circuit 140 is constituted with a current source circuit configured to be capable of switching an amount of turn-off current I_{OFF}. The turn-off circuit 140 according to this embodiment includes a third switching current source 142, a fourth switching current source 144, a third base current source 146, and a fourth base current source 148. The third switching current source 142, the fourth switching current source 144, the third base current source 146, and the fourth base current source 148 are connected in parallel between the high-side gate line 178 and the switching line 174.

Each of the third switching current source 142 and the fourth switching current source 144 is configured to be capable of switching an amount of current, and is a current DAC in this embodiment. The third switching current source 142 and the fourth switching current source 144 sink a third switching current I_{OFF_SL} and a fourth switching current I_{OFF_SH} from the high-side gate pin HG, respectively.

The third base current source 146 and the fourth base current source 148 generate constant base currents in the same direction as those of the third switching current I_{OFF_SL} and the fourth switching current I_{OFF_SH}, respectively. Specifically, the third base current source 146 sinks a third base current I_{OFF_BL} from the high-side gate pin HG, and the fourth base current source 148 sinks a fourth base current I_{OFF_BH} from the high-side gate pin HG. The sum of the currents sunk by these current sources is the turn-off current I_{OFF}. That is, I_{OFF}=I_{OFF_SL}+I_{OFF_SH}+I_{OFF_BL}+I_{OFF_BH}.

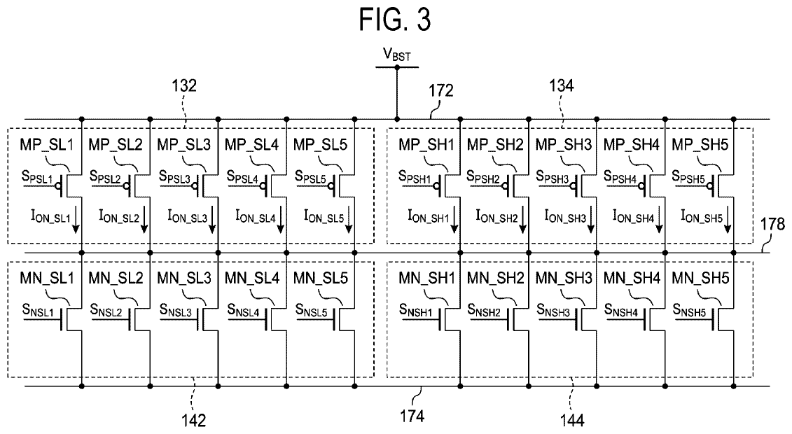

FIG. 3 is a circuit diagram showing the first switching current source 132 and the second switching current source 134 of the turn-on circuit 130 according to this embodiment, and the third switching current source 142 and fourth switching current source 144 of the turn-off circuit 140 according to this embodiment.

The first switching current source 132 includes a plurality of first transistors MP_SL1 to MP_SL5 which are connected in parallel to each other. The number of first transistors MP_SL1 to MP_SL5 is m (m is an integer of 2 or greater). In this embodiment, m=5. The number of first transistors is not limited to 5, and may be 2 to 4, or 6 or more.

The first switching current source 132 is configured to source the first switching current I_{ON_SL} corresponding to which of the plurality of first transistors MP_SL1 to MP_SL5 is turned on. Each of the plurality of first transistors MP_SL1 to MP_SL5 is constituted with a P-channel MOS transistor, and is provided between the bootstrap line 172 and the high-side gate line 178.

Each of the plurality of first transistors MP_SL1 to MP_SL5 according to this embodiment is configured to operate in a saturation region. By operating the first transistors MP_SL1 to MP_SL5 in the saturation region, a fluctuation in a drain current of each of the first transistors MP_SL1 to MP_SL5 is suppressed when the fluctuation occurs in the drain-source voltage.

The on/off states of the first transistors MP_SL1 to MP_SL5 are controlled by gate signals S_{PSL1} to S_{PSL5} input to their gates, respectively. When the first transistors MP_SL1 to MP_SL5 are turned on, drain currents I_{ON_SL1} to I_{ON_SL5} flow through the first transistors MP_SL1 to MP_SL5, respectively. The sum of the drain currents flowing through the first transistors MP_SL1 to MP_SL5 in the turn-on state is the first switching current I_{ON_SL}.

A range of the first switching current I_{ON_SL} (excluding a case where all the first transistors are turned off) is I_{SL_MIN}≤I_{ON_SL}≤I_{SL_MAX}. In this embodiment, I_{ON_SL1}<I_{ON_SL2}<I_{ON_SL3}<I_{ON_SL4}<I_{ON_SL5}. Therefore, the non-zero minimum value I_{SL_MIN} of the first switching current I_{ON_SL} is I_{ON_SL1}, and the maximum value I_{SL_MAX} of the first switching current I_{ON_SL} is I_{ON_SL1}+I_{ON_SL}2+I_{ON_SL}3+I_{ON_SL}4+I_{ON_SL5}.

The second switching current source 134 includes a plurality of second transistors MP_SH1 to MP_SH5 which are connected in parallel to each other. The number of second transistors MP_SH1 to MP_SH5 is n (n is an integer of 2 or greater). In this embodiment, n=5. The number of second transistors is not limited to 5, and may be 2 to 4, or 6 or more.

The second switching current source 134 is configured to source the second switching current I_{ON_SH} corresponding to which of the plurality of second transistors MP_SH1 to MP_SH5 is turned on. Each of the plurality of second transistors MP_SH1 to MP_SH5 according to this embodiment is constituted with a P-channel MOS transistor, and is provided between the bootstrap line 172 and the high-side gate line 178. Each of the plurality of second transistors MP_SH1 to MP_SH5 according to this embodiment is configured to operate in a saturation region.

The on/off states of the second transistors MP_SH1 to MP_SH5 are controlled by gate signals S_{PSH1} to S_{PSH5} input to their gates, respectively. When the second transistors MP_SH1 to MP_SH5 are turned on, drain currents I_{ON_SH1} to I_{ON_SH5} flow through the second transistors MP_SH1 to MP_SH5, respectively. The sum of the drain currents flowing through the second transistors MP_SH1 to MP_SH5 in the turn-on state is the second switching current I_{ON_SH}.

A range of the second switching current I_{ON_SH} (excluding a case where all the second transistors are turned off) is I_{SH_MIN}≤I_{ON_SH}≤I_{SH_MAX}. In this embodiment, I_{ON_SH1}<I_{ON_SH2}<I_{ON_SH3}<I_{ON_SH4}<I_{ON_SH5}. Therefore, the non-zero minimum value I_{SH_MIN} of the second switching current I_{ON_SH} is I_{ON_SH1}, and the maximum value I_{SH_MAX} of the second switching current I_{ON_SH} IS I_{ON_SH1}+I_{ON_SH2}+I_{ON_SH3}+I_{ON_SH4}+I_{ON_SH5}.

In this embodiment, the range of the first switching current I_{ON_SL} partially overlaps with the range of the second switching current I_{ON_SH}. Specifically, the minimum value I_{SH_MIN} of the second switching current I_{ON_SH} is between the minimum value I_{SL_MIN} of the first switching current I_{ON_SL} and the maximum value I_{SL_MAX} of the first switching current I_{ON_SL}. That is, I_{SL_MIN}<I_{SH_MIN}<I_{SL_MAX}. The maximum value I_{SH_MAX} of the second switching current I_{ON_SH} is higher than the maximum value I_{SL_MAX} of the first switching current I_{ON_SL}. That is, I_{SL_MAX}<I_{SH_MAX}.

For example, the range of the first switching current I_{ON_SL} is assumed to be 1 mA to 31 mA and the range of the second switching current I_{ON_SH} is assumed to be 16 mA to 511 mA. In this case, the range of the first switching current I_{ON_SL} and the range of the second switching current I_{ON_SH} overlap with each other in the range of 16 mA to 31 mA. By partially overlapping the range of the first switching current I_{ON_SL} with the range of the second switching current I_{ON_SH} in this manner, it is possible to improve DNL (differential non-linearity) in the overlapping range.

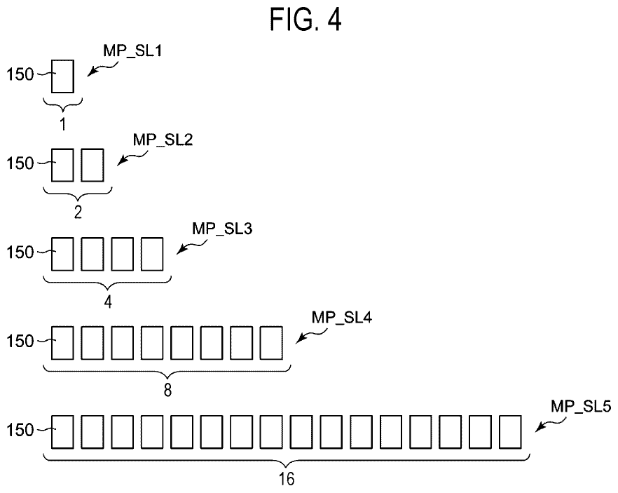

FIG. 4 is a diagram illustrating a configuration of the first transistors MP_SL1 to MP_SL5 according to this embodiment. Each of the first transistors MP_SL1 to MP_SL5 according to this embodiment is constituted with a MOS transistor 150 having a first gain. Each of the first transistors MP_SL1 to MP_SL5 is constituted with one or more MOS transistors 150. An α-th (α is an integer from 1 to m) first transistor MP_SLα of the plurality of first transistors MP_SL1 to MP_SL5 is constituted with 2^{α-1} MOS transistors 150.

For example, the first transistor MP_SL1 is constituted with one (α=0) MOS transistor 150, the first transistor MP_SL2 is constituted with two (α=1) MOS transistors 150, the first transistor MP_SL3 is constituted with four (α=2) MOS transistors 150, the first transistor MP_SL4 is constituted with eight (α=3) MOS transistors 150, and the first transistor MP_SL5 is constituted with sixteen (α=4) MOS transistors 150. Therefore, the first switching current source 132 is constituted with thirty-one MOS transistors 150.

By configuring the first transistors MP_SL1 to MP_SL5 in this manner, the drain currents I_{ON_SL1} to I_{ON_SL5} of the on-state first transistors MP_SL1 to MP_SL5 have binary-weighted magnitudes. Specifically, when the drain current I_{ON_SL1} of the on-state first transistor MP_SL1 is 1 mA, the drain currents of the on-state first transistors MP_SL2 to MP_SL5 are I_{ON_SL2}=2 mA, I_{ON_SL3}=4 mA, I_{ON_SL4}=8 mA, and I_{ON_SL5}=16 mA, respectively. Thus, the range of the first switching current I_{ON_SL} is 1 mA to 31 mA.

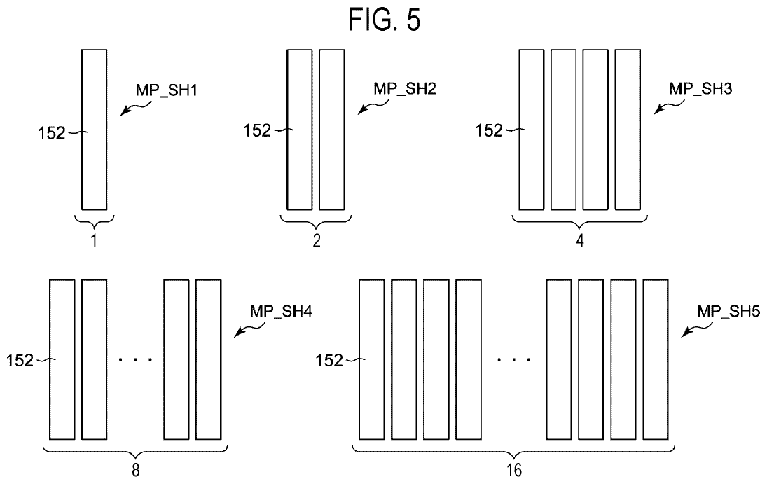

FIG. 5 is a diagram illustrating a configuration of the second transistors MP_SH1 to MP_SH5 according to this embodiment. Each of the second transistors MP_SH1 to MP_SH5 according to this embodiment is constituted with a MOS transistor 152 having a second gain greater than the first gain.

A size of the MOS transistors 152 constituting the second transistors MP_SH1 to MP_SH5 is larger than that of the MOS transistors 150 constituting the first transistors MP_SL1 to MP_SL5. Specifically, W/L (channel width/gate length) of the MOS transistors 152 is larger than that of the MOS transistors 150. For example, the channel width of the MOS transistors 152 may be longer than the channel width of the MOS transistors 150.

Each of the second transistors MP_SH1 to MP_SH5 is constituted with one or more MOS transistors 152. A β-th (β is an integer from 1 to n) second transistor MP_SHβ of the plurality of second transistors MP_SH1 to MP_SH5 is constituted with 2^{β-1} MOS transistors 152.

For example, the second transistor MP_SH1 is constituted with one (β=0) MOS transistor 152, the second transistor MP_SH2 is constituted with two (β=1) MOS transistors 152, the second transistor MP SH3 is constituted with four (β=2) MOS transistors 152, the second transistor MP SH4 is constituted with eight (β=3) MOS transistors 152, and the second transistor MP_SH5 is constituted with sixteen (β=4) MOS transistors 152. Therefore, the second switching current source 134 is constituted with thirty-one MOS transistors 152.

By configuring the second transistors MP_SH1 to MP_SH5 in this manner, the drain currents I_{ON_SH1} to I_{ON_SH5} of the on-state second transistors MP_SH1 to MP_SH5 have binary-weighted magnitudes. Here, since the second gain is greater than the first gain, the drain current I_{ON_SH1} flowing through the second transistor MP_SH1 in the turn-on state is greater than the drain current I_{ON_SL1} flowing through the first transistor MP_SL1 in the turn-on state. In this embodiment, the drain current I_{ON_SH1} of the second transistor MP_SH1 in the turn-on state is set to 16 mA. In this case, the drain currents of the second transistors MP_SH2 to MP_SH5 in the turn-on state are I_{ON_SH}2=32 mA, I_{ON_SH}3=64 mA, I_{ON_SH}4=128 mA, and I_{ON_SH}5=256 mA, respectively. Thus, the range of the second switching current I_{ON_SH} is 16 mA to 511 mA.

The minimum value I_{SL_MIN} of the first switching current I_{ON_SL} is smaller than the minimum value I_{SH_MIN} of the second switching current I_{ON_SH}. For example, the minimum value I_{SL_MIN} of the first switching current I_{ON_SL} is 1 mA, and the minimum value I_{SH_MIN} of the second switching current I_{ON_SH} is 16 mA. Therefore, the accuracy of the first switching current I_{ON_SL} is higher than the accuracy of the second switching current I_{ON_SH}. Therefore, either the first switching current source 132 or the second switching current source 134 may be used depending on the required current accuracy and current capability.

Returning to FIG. 3, configurations of the third switching current source 142 and the fourth switching current source 144 of the turn-off circuit 140 will be described.

The third switching current source 142 includes five fifth transistors MN_SL1 to MN_SL5 connected in parallel to each other. The number of fifth transistors is not limited to 5, and may be 2 to 4, or 6 or more. Each of the plurality of fifth transistors MN_SL1 to MN_SL5 according to this embodiment is constituted with an N-channel MOS transistor, and is provided between the high-side gate line 178 and the switching line 174. Each of the plurality of fifth transistors MN_SL1 to MN_SL5 according to this embodiment is configured to operate in a saturation region.

The third switching current source 142 is configured to sink the third switching current I_{OFF} SL corresponding to which of the plurality of fifth transistors MN_SL1 to MN_SL5 is turned on. The on/off states of the fifth transistors MN_SL1 to MN_SL5 are controlled by gate signals S_{NSL1} to S_{NSL5} input to their gates, respectively. The sum of the drain currents flowing through the fifth transistors MN_SL1 to MN_SL5 in the turn-on state is the third switching current I_{OFF_SL}.

Each of the fifth transistors MN_SL1 to MN_SL5 may be constituted with a MOS transistor having a third gain. For example, like the first transistors MP_SL1 to MP_SL5, the fifth transistors MN_SL1 to MN_SL5 may be constituted with 2^{α-1} (α is an integer from 1 to 5) MOS transistors having a third gain.

The fourth switching current source 144 includes five sixth transistors MN_SH1 to MN_SH5 connected in parallel to each other. The number of sixth transistors is not limited to 5, and may be 2 to 4, or 6 or more. Each of the plurality of sixth transistors MN_SH1 to MN_SH5 according to this embodiment is constituted with an N-channel MOS transistor, and is provided between the high-side gate line 178 and the switching line 174. Each of the plurality of sixth transistors MN_SH1 to MN_SH5 according to this embodiment is configured to operate in a saturation region.

The fourth switching current source 144 is configured to sink the fourth switching current I_{OFF} SL corresponding to which of the plurality of sixth transistors MN_SH1 to MN_SH5 is turned on. The on/off states of the sixth transistors MN_SH1 to MN_SH5 are controlled by gate signals S_{NSH1} to S_{NSH5} input to their gates, respectively. The sum of the drain currents flowing through the sixth transistors MN_SH1 to MN_SH5 in the turn-on state is the fourth switching current I_{OFF_SH}.

Each of the sixth transistors MN_SH1 to MN_SH5 may be constituted with a MOS transistor having a fourth gain greater than the third gain. Specifically, like the first transistors MP_SL1 to MP_SL5, the sixth transistors MN_SH1 to MN_SH5 may be constituted with 2^{β-1} (β is an integer from 1 to 5) MOS transistors having a fourth gain.

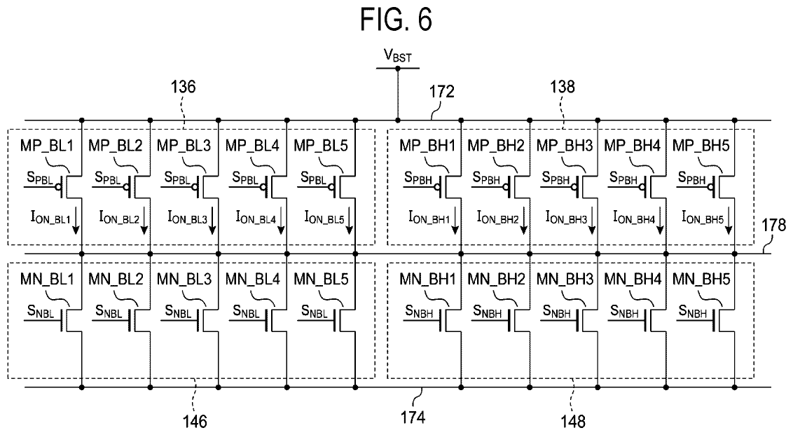

FIG. 6 is a circuit diagram showing the first base current source 136 and the second base current source 138 of the turn-on circuit 130 according to this embodiment, and the third base current source 146 and the fourth base current source 148 of the turn-off circuit 140 according to this embodiment.

The first base current source 136 includes third transistors MP_BL1 to MP_BL5, each constituted with a MOS transistor 150 having a first gain. The third transistors MP_BL1 to MP_BL5 are connected in parallel to each other. Each of the third transistors MP_BL1 to MP_BL5 is provided between the bootstrap line 172 and the high-side gate line 178.

The first base current source 136 is configured to source the first base current I_{ON_SL} corresponding to which of the five third transistors MP_BL1 to MP_BL5 is turned on. The on/off states of the third transistors MP_BL1 to MP_BL5 are controlled by a common gate signal S_{PBL}. The drain currents I_{ON_BL1} to I_{ON_BL5} flow through the third transistors MP_BL1 to MP_BL5 in the turn-on state, respectively. The sum of the drain currents flowing through the third transistors MP_BL1 to MP_BL5 is the first base current I_{ON_SL}.

Further, the first base current source 136 may be configured to function as the current DAC. Specifically, the third transistors MP_BL1 to MP_BL5 may be configured so that the drain currents I_{ON_BL1} to I_{ON_BL5} have binary-weighted magnitudes, similar to the first transistors MP_SL1 to MP_SL5. The on/off states of the third transistors MP_BL1 to MP_BL5 may be individually switched. This holds true in the second base current source 138, the third base current source 146, and the fourth base current source 148.

The second base current source 138 includes fourth transistors MP_BH1 to MP_BH5, each constituted with a MOS transistor 152 having a second gain. The fourth transistors MP_BH1 to MP_BH5 are connected in parallel to each other. Each of the fourth transistors MP_BH1 to MP_BH5 is provided between the bootstrap line 172 and the high-side gate line 178.

The second base current source 138 is configured to source the second base current I_{ON_SH} corresponding to which of the five fourth transistors MP_BH1 to MP_BH5 is turned on. The on/off states of the fourth transistors MP_BH1 to MP_BH5 are controlled by a common gate signal S_{PBH}. The drain currents I_{ON_BH1} to I_{ON_BH5} flow through the fourth transistors MP_BH1 to MP_BH5 in the turn-on state, respectively. The sum of the drain currents flowing through the fourth transistors MP_BH1 to MP_BH5 is the second base current I_{ON_SH}.

The third base current source 146 includes seventh transistors MN_BL1 to MN_BL5, each constituted with a MOS transistor having a third gain. The seventh transistors MN_BL1 to MN_BL5 are connected in parallel to each other. Each of the seventh transistors MN_BL1 to MN_BL5 is provided between the high-side gate line 178 and the switching line 174.

The third base current source 146 is configured to sink the third base current I_{OFF_BL} corresponding to which of the five seventh transistors MN_BL1 to MN_BL5 is turned on. The on/off states of the seventh transistors MN_BL1 to MN_BL5 are controlled by a common gate signal S_{NBL}. The drain currents flow through the seventh transistors MN_BL1 to MN_BL5 in the turn-on state, respectively. The sum of the drain currents flowing through the seventh transistors MN_BL1 to MN_BL5 is the third base current I_{OFF_BL}.

The fourth base current source 148 includes eighth transistors MN_BH1 to MN_BH5, each constituted with a MOS transistor having a fourth gain. The eighth transistors MN_BH1 to MN_BH5 are connected in parallel to each other. Each of the eighth transistors MN_BH1 to MN_BH5 is provided between the high-side gate line 178 and the switching line 174.

The fourth base current source 148 is configured to sink the fourth base current I_{OFF} BH corresponding to which of the five eighth transistors MN_BH1 to MN_BH5 is turned on. The on/off states of the eighth transistors MN_BH1 to MN_BH5 are controlled by a common gate signal S_{NBH}. The drain currents flow through the eighth transistors MN_BH1 to MN_BH5 in the turn-on state, respectively. The sum of the drain currents flowing through the eighth transistors MN_BH1 to MN_BH5 is the fourth base current I_{OFF} BH.

Returning to FIG. 1, the control circuit 100 according to this embodiment will be described. The control circuit 100 includes the logic circuit 102, level shifter blocks 104a and 104b, a high-side selector 108a, and a low-side selector 108b.

The logic circuit 102 controls the high-side driver 120a and the low-side driver 120b, and more specifically, the turn-on circuit 130 and the turn-off circuit 140. The logic circuit 102 according to this embodiment may individually control the on/off states of the first transistors MP_SL1 to MP_SL5, the second transistors MP_SH1 to MP_SH5, the fifth transistors MN_SL1 to MN_SL5, and the sixth transistors MN_SH1 to MN_SH5. The logic circuit 102 according to this embodiment may further control the first base current source 136, the second base current source 138, the third base current source 146, and the fourth base current source 148.

Next, a configuration for controlling the turn-on circuit 130 of the high-side driver 120a will be mainly described in relation to the control circuit 100. The configuration for controlling the turn-on circuit 130 of the high-side driver 120a may also be applied to a configuration for controlling the turn-off circuit 140 of the high-side driver 120a or the turn-on circuit and turn-off circuit of the low-side driver 120b.

The control circuit 100 according to this embodiment is configured to be capable of switching a mode between a first mode in which the on/off states of the plurality of first transistors MP_SL1 to MP_SL5 are individually controlled and a second mode in which the on/off states of the plurality of second transistors MP_SH1 to MP_SH5 are individually controlled. In the first mode, the control circuit 100 individually controls the on/off states of the plurality of first transistors MP_SL1 to MP_SL5 and turns off all of the plurality of second transistors MP_SH1 to MP_SH5. In the second mode, the control circuit 100 individually controls the on/off states of the plurality of second transistors MP_SH1 to MP_SH5 and turns off all of the plurality of first transistors MP_SL1 to MP_SL5.

The logic circuit 102 according to this embodiment generates a signal for controlling the high-side driver 120a and a signal for controlling the low-side driver 120b based on the input signal S_{IN} and the sensor signal S_{SNS}. The signal for controlling the high-side driver 120a includes a multi-bit first control signal S_{H_1} and a single-bit first mode signal S_{H_3} indicating the mode of the control circuit 100.

The first mode signal S_{H_3} may be, for example, at a high level in the first mode and at a low level in the second mode. Each bit of the control signal S_{H_1} is associated with a respective one of the plurality of first transistors MP_SL1 to MP_SL5 and a respective one of the plurality of second transistors MP_SH1 to MP_SH5. In this embodiment, the first control signal S_{H_1} has five bits, and a bit (x−1) (x is an integer from 1 to 5) of the first control signal S_{H_1} corresponds to the first transistor MP_SLx and the second transistor MP_SHx. The number of bits of the first control signal S_{H_1} may be adjusted as appropriate according to the number of first and second transistors.

In this embodiment, among the first transistors MP_SL1 to MP_SL5 and the second transistors MP_SH1 to MP_SH5, the on/off states of transistors in the mode indicated by the first mode signal S_{H_3} may be switched, and the remaining transistors are turned off. For example, when the first mode signal S_{H_3} indicates the first mode, the on/off states of the first transistors MP_SL1 to MP_SL5 may be switched, and all of the second transistors MP_SH1 to MP_SH5 are turned off. Further, when the first mode signal S_{H_3} indicates the second mode, the on/off states of the second transistors MP_SH1 to MP_SH5 may be switched, and all of the first transistors MP_SL1 to MP_SL5 are turned off.

Among the plurality of first transistors MP_SL1 to MP_SL5 and the plurality of second transistors MP_SH1 to MP_SH5, the on/off states of the plurality of switchable transistors are individually switched in response to the first control signal S_{H_1}. For example, when the first mode signal S_{H_3} indicates the first mode, the on/off states of the first transistors MP_SL1 to MP_SL5 are individually switched. Further, when the first mode signal S_{H_3} indicates the second mode, the on/off states of the second transistors MP_SH1 to MP_SH5 are individually switched.

The level shifter block 104a level-shifts the first control signal S_{H_1} to generate a second control signal S_{H_2}, and level-shifts the first mode signal S_{H_3} to generate a second mode signal S_{H_4}. The second control signal S_{H_2} is a 5-bit signal, and the second mode signal S_{H_4} is a single-bit signal. The second control signal S_{H_2} and the second mode signal S_{H_4} are respectively transmitted to the high-side selector 108a.

Based on the second control signal S_{H_2} and the second mode signal S_{H_4}, the high-side selector 108a generates a third control signal S_{H_5} for controlling the on/off states of the first transistors MP_SL1 to MP_SL5 and the on/off states of the second transistors MP_SH1 to MP_SH5. The third control signal S_{H_5} includes a 5-bit signal for controlling the on/off states of the first transistors MP_SL1 to MP_SL5 and a 5-bit signal for controlling the on/off states of the second transistors MP_SH1 to MP_SH5.

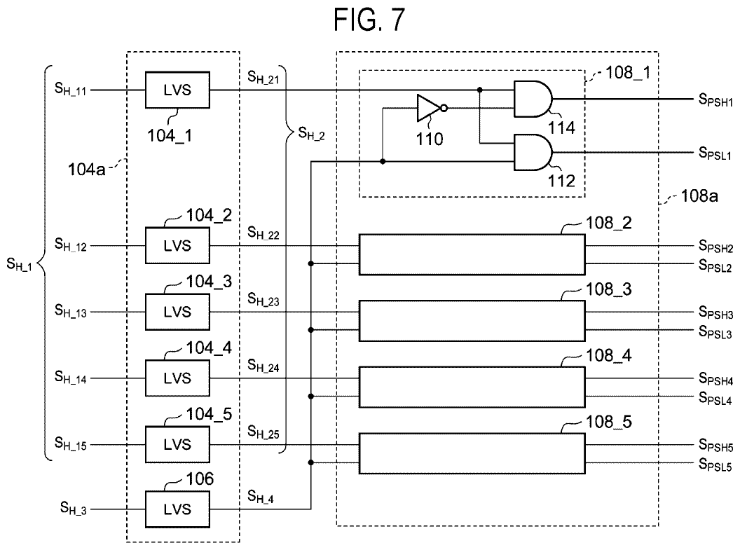

FIG. 7 is a block diagram illustrating configurations of the level shifter block 104a and the high-side selector 108a according to this embodiment. The level shifter block 104b and the low-side selector 108b may be configured in the same manner as those of the level shifter block 104a and the high-side selector 108a.

The level shifter block 104a according to this embodiment includes a plurality of control level shifters 104_1 to 104_5 and a mode level shifter 106.

The plurality of control level shifters 104_1 to 104_5 level-shift signals S_{H_11} to S_{H_15} of bits 0 to 4 that make up the first control signal S_{H_1}, respectively, to generate the second control signal S_{H_2} which is made up of signals S_{H_21} to S_{H_25} of bits 0 to 4. Specifically, the plurality of control level shifters 104_1 to 104_5 each level-shift a signal of the corresponding bit in the first control signal S_{H_1}. The bit (x−1) (x is an integer from 1 to 5) of the first control signal S_{H_1} corresponds to the control level shifter 104_x.

The mode level shifter 106 level-shifts the first mode signal S_{H_1} to generate the second mode signal S_{H_4}.

Based on the second control signal S_{H_2} and the second mode signal S_{H_4}, the high-side selector 108a generates gate signals for controlling the on/off states of transistors of the first transistors MP_SL1 to MP_SL5 and the second transistors MP_SH1 to MP_SH5 in the mode indicated by the mode signals (the first mode signal S_{H_3} and the second mode signal S_{H_4}), and gate signals for turning off the remaining transistors.

For example, when the first mode signal S_{H_3} indicates the first mode, the high-side selector 108a generates the gate signals S_{PSL1} to S_{PSL5} for individually controlling the on/off states of the first transistors MP_SL1 to MP_SL5 and the gate signals S_{PSH1} to S_{PSH5} for turning off all of the second transistors MP_SH1 to MP_SH5. When the first mode signal S_{H_3} indicates the second mode, the high-side selector 108a generates the gate signals S_{PSH1} to S_{PSH5} for individually controlling the on/off states of the second transistors MP_SH1 to MP_SH and the gate signals S_{PSL1} to S_{PSL5} for turning off all of the first transistors MP_SL1 to MP_SL5.

The high-side selector 108a according to this embodiment includes a plurality of selection circuits 108_1 to 108_5. Each of the plurality of selection circuits 108_1 to 108_5 generates a gate signal for controlling a corresponding first transistor and a corresponding second transistor based on a corresponding bit of the second control signal S_{H_2} and the second mode signal S_{H_4}. The selection circuit 108_x (x is an integer from 1 to 5) corresponds to the bit (x−1) of the second control signal S_{H_2}, the first transistor MP_SLx, and the second transistor MP_SHx.

The plurality of selection circuits 108_1 to 108_5 may have the same configuration. Here, a configuration of the selection circuit 108_1 will be described. The selection circuit 108_1 includes a NOT gate 110, a first AND gate 112, and a second AND gate 114.

The NOT gate 110 inverts a logic level of the second mode signal S_{H_4} to generate an output signal. The first AND gate 112 performs a logical AND operation on the signal S_{H_21} from the control level shifter 104_1 and the second mode signal S_{H_4} to generate the gate signal S_{PSL1} for the first transistor MP_SL1. The second AND gate 114 performs a logical AND operation on the signal S_{H_21} from the control level shifter 104_1 and the output signal of the NOT gate 110 to generate the gate signal S_{PSH1} for the second transistor MP_SH1.

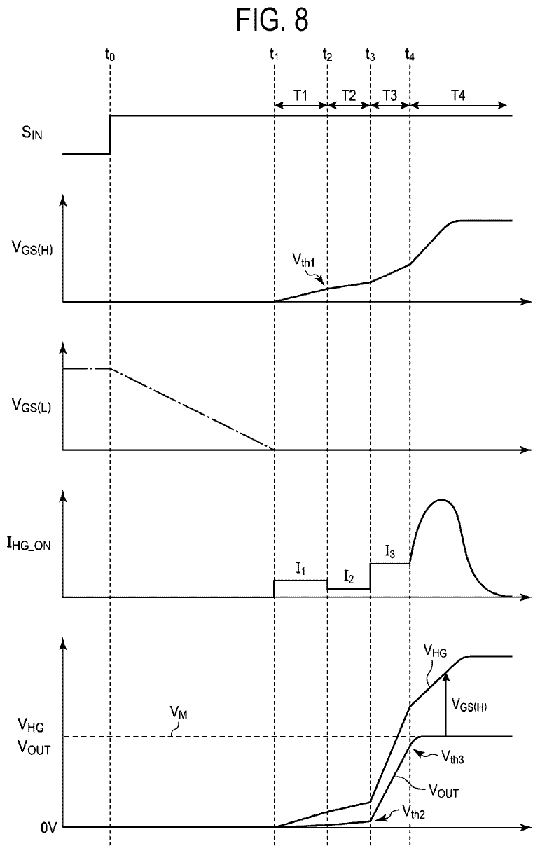

FIG. 8 is a waveform diagram showing an operation example of the gate driver circuit 10 according to this embodiment. The input signal S_{IN} is a logic signal indicating the mode of the control circuit 100. V_{GS(H)} is a gate-source voltage of the high-side transistor MH. V_{GS(L)} is a gate-source voltage of the low-side transistor ML. I_{HG_ON} is a turn-on current sourced to the high-side transistor MH. V_{OUT} indicates an output voltage of the switching circuit 1. V_{HG} represents a gate voltage of the high-side transistor MH.

Before time to, the input signal S_{IN} is at a low level, the high-side transistor MH is turned off, the low-side transistor ML is turned on, and the output voltage V_{OUT} is at a low voltage (0 V). At time t₀, the input signal S_{IN} transitions to a high level. This causes the low-side driver 120b to lower the gate-source voltage V_{GS(L)} of the low-side transistor ML and turn off the low-side transistor ML.

At time t₁, when the gate-source voltage V_{GS(L)} of the low-side transistor ML falls below a predetermined threshold voltage, the control circuit 100 enables the turn-on circuit 130 of the high-side driver 120a.

During a first period T1, the turn-on circuit 130 generates the turn-on current I_{HG_ON} of a first current amount I₁.

Next, at time t₂, when the gate-source voltage V_{GS(H)} of the high-side transistor MH exceeds the first threshold voltage Vₜₕ₁, the operation transitions to a second period T2 (minimum current section). During the second period T2, the turn-on current I_{HG_ON} reaches its minimum current amount I₂. The current amount I₂ in the minimum current section is less than the first current amount I₁ in the first period T1. Therefore, a rate of increase of the gate-source voltage V_{GS(H)} of the high-side transistor MH becomes slower than that in the first period T1.

Next, at time t₃, when the output voltage V_{OUT} exceeds the second threshold voltage Vₜₕ₂, the operation transitions to a third period T3. During the third period T3, the turn-on current I_{HG_ON} reaches a third current amount I₃ which is greater than the minimum current amount I₂. The third current amount I₃ may be greater than the first current amount I₁. As a result, the rate of increase of the gate-source voltage V_{GS(H)} of the high-side transistor MH during the third period T3 becomes faster.

Next, at time t₄, when the output voltage V_{OUT} exceeds the third threshold voltage Vₜₕ₃ defined near the input voltage V_{M}, the operation transitions to a fourth period T4. During the fourth period T4, the turn-on circuit 130 enters a strong-on state, the gate voltage V_{HG} of the high-side transistor MH is fixed to a high-level voltage (the bootstrap voltage V_{BST}), and the high-side transistor MH is fixed to a strong-on state.

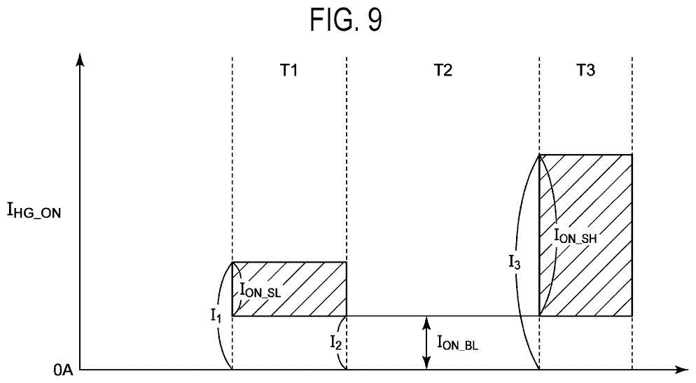

FIG. 9 is a waveform diagram showing an operation example of the turn-on circuit 130 according to this embodiment. During the first period T1 through the third period T3, the first base current source 136 is turned on, and the second base current source 138 is turned off. This generates a constant amount of first base current I_{ON_BL}.

In the first period T1, the control circuit 100 is in the first mode. During the first period T1, the control circuit 100 turns on at least one (for example, all five) of the plurality of first transistors MP_SL1 to MP_SL5 of the first switching current source 132 and turns off all of the plurality of second transistors MP_SH1 to MP_SH5 of the second switching current source 134. This generates the first switching current I_{ON_SL}. In the first period T1, the sum of the first base current I_{ON_BL} and the first switching current I_{ON_SL} is the turn-on current I_{HG_ON} (I_{HG_ON}=I_{ON_BL}+I_{ON_SL}).

During the second period T2 following the first period T1, the control circuit 100 turns off all of the plurality of first transistors MP_SL1 to MP_SL5 of the first switching current source 132 and the plurality of second transistors MP_SH1 to MP_SH5 of the second switching current source 134. As a result, the turn-on current I_{HG_ON} becomes the first switching current I_{ON_SL} (I_{HG_ON}=I_{ON_SL}). During the second period T2, the mode of the control circuit 100 switches from the first mode to the second mode.

During the third period T3 following the second period T2, the control circuit 100 turns off all of the plurality of first transistors MP_SL1 to MP_SL5 of the first switching current source 132 and turns on at least one (for example, all five) of the plurality of second transistors MP_SH1 to MP_SH5 of the second switching current source 134. This generates the second switching current I_{ON_SH}. In the third period T3, the sum of the first base current I_{ON_BL} and the second switching current I_{ON_SH} is the turn-on current I_{HG_ON} (I_{HG_ON}=I_{ON_BL}+I_{ON_SH}). The amount of the second switching current I_{ON_SH} during the third period T3 is greater than the amount of the first switching current I_{ON_SL} during the first period T1.

Further, during the fourth period T4 following the third period T3, the control circuit 100 may turn on at least one (for example, all five) of the plurality of second transistors MP_SH1 to MP_SH5 of the second switching current source 134, continuing from the third period T3.

The configuration of the gate driver circuit 10 according to this embodiment and the operation example thereof have been described above. The gate driver circuit 10 according to this embodiment includes the control circuit 100, the turn-on circuit 130, and the turn-off circuit 140. The control circuit 100 controls the turn-on circuit 130 and the turn-off circuit 140. The turn-on circuit 130 sources the turn-on current to the gate of the power transistor (the high-side transistor MH or the low-side transistor ML) during the turn-on period of the power transistor. The turn-off circuit 140 sinks the turn-off current from the gate of the power transistor during the turn-off period of the power transistor.

The turn-on circuit 130 or the turn-off circuit 140 includes the current source circuit configured to be capable of switching the amount of turn-on current or turn-off current. The current source circuit includes the first switching current source 132 (or the third switching current source 142) and the second switching current source 134 (or the fourth switching current source 144).

The first switching current source 132 (or the third switching current source 142) includes the plurality of first transistors MP_SL1 to MP_SL5 (or the fifth transistors MN_SL1 to MN_SL5) connected in parallel to each other. The first switching current source 132 (or the third switching current source 142) is configured to source to (or sink from) the gate the first switching current I_{ON_SL} (or the third switching current I_{OFF_SL}) corresponding to the first transistor (or the fifth transistor) that is turned on among the plurality of first transistors MP_SL1 to MP_SL5 (or the fifth transistors MN_SL1 to MN_SL5).

The second switching current source 134 (or the fourth switching current source 144) includes the plurality of second transistors MP_SH1 to MP_SH5 (or the sixth transistors MN_SH1 to MN_SH5) connected in parallel to each other. The second switching current source 134 (or the fourth switching current source 144) is configured to source to (or sink from) the gate the second switching current I_{ON_SH} (or the fourth switching current I_{OFF_SH}) corresponding to the second transistor (or the sixth transistor) that is turned on among the plurality of second transistors MP_SH1 to MP_SH5 (or the sixth transistors MN_SH1 to MN_SH5).

The first transistors MP_SL1 to MP_SL5 (or the fifth transistors MN_SL1 to MN_SL5) are constituted with MOS transistors having the first gain (or the third gain). The second transistors MP_SH1 to MP_SH5 (or the sixth transistors MN_SH1 to MN_SH5) are constituted with MOS transistors having the second gain (or the fourth gain) greater than the first gain (or the third gain).

The control circuit 100 individually controls the on/off states of the plurality of first transistors MP_SL1 to MP_SL5 (or the fifth transistors MN_SL1 to MN_SL5) or the on/off states of the plurality of second transistors MP_SH1 to MP_SH5 (or the sixth transistors MN_SH1 to MN_SH5).

According to this configuration, the control circuit 100 may implement the required turn-on current (or turn-off current) by individually switching the on/off states of the first transistors MP_SL1 to MP_SL5 or the second transistors MP_SH1 to MP_SH5. In this case, the first transistors MP_SL1 to MP_SL5 and the second transistors MP_SH1 to MP_SH5 are configured with MOS transistors having two types of gain. This allows the transistor area to be smaller than when all transistors are configured with MOS transistors having one type of gain. As a result, it becomes possible to drive the power transistor with transistors having a smaller area.

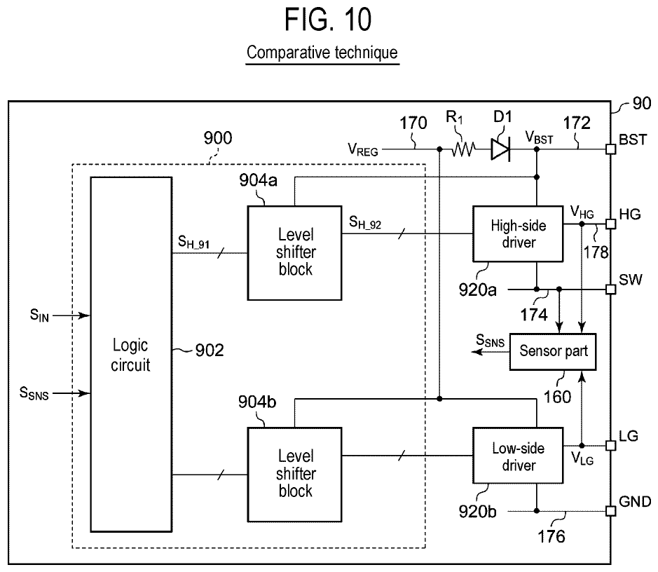

Advantages of the gate driver circuit 10 according to this embodiment become even clearer when compared with a gate driver circuit according to a comparative technique. FIG. 10 is a block diagram of a gate driver circuit 90 according to the comparative technique. The gate driver circuit 90 according to the comparative technique is different from the gate driver circuit 10 according to this embodiment mainly in configurations of a control circuit 900, a high-side driver 920a, and a low-side driver 920b.

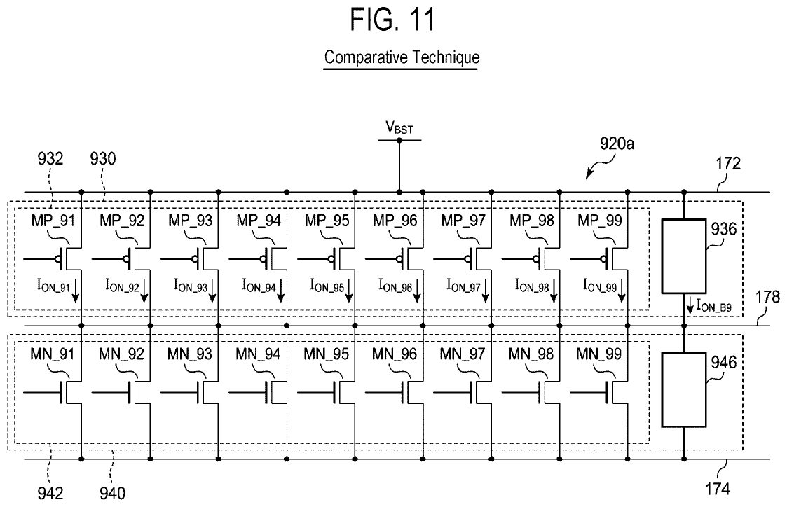

FIG. 11 is a block diagram of the high-side driver 920a according to the comparative technique. Further, the low-side driver 920b may be configured in the same manner as the high-side driver 920a. The high-side driver 920a according to the comparative technique includes a turn-on circuit 930 and a turn-off circuit 940.

The turn-on circuit 930 includes a switching current source 932 that sources a switching current I_{ON_9} to the high-side gate line 178, and a base current source 936 that sources a constant amount of current I_{ON_B9} to the high-side gate line 178. The switching current source 932 is configured to be capable of switching the amount of switching current I_{ON_9}. The switching current source 932 includes nine transistors MP_91 to MP_99, each constituted with a P-channel MOS transistor. When the transistors MP_91 to MP_99 are turned on, they source drain currents I_{ON_91} to I_{ON_99}. The sum of the drain currents I_{ON_91} to I_{ON_99} sourced by the on transistors MP_91 to MP_99 is the switching current I_{ON_9} sourced by the switching current source 932.

The turn-off circuit 940 includes a switching current source 942 that sinks a switching current from the high-side gate line 178, and a base current source 946 that sinks a constant amount of current I_{OFF_B9} from the high-side gate line 178. The switching current source 942 is configured to be capable of switching the amount of switching current to be sunk. The switching current source 942 includes nine transistors MN_91 to MN_99, each constituted with an N-channel MOS transistor. When the transistors MN_91 to MN_99 are turned on, they sink drain currents. The sum of the drain currents sunk by the turned-on transistors MN_91 to MN_99 is the switching current sunk by the switching current source 942.

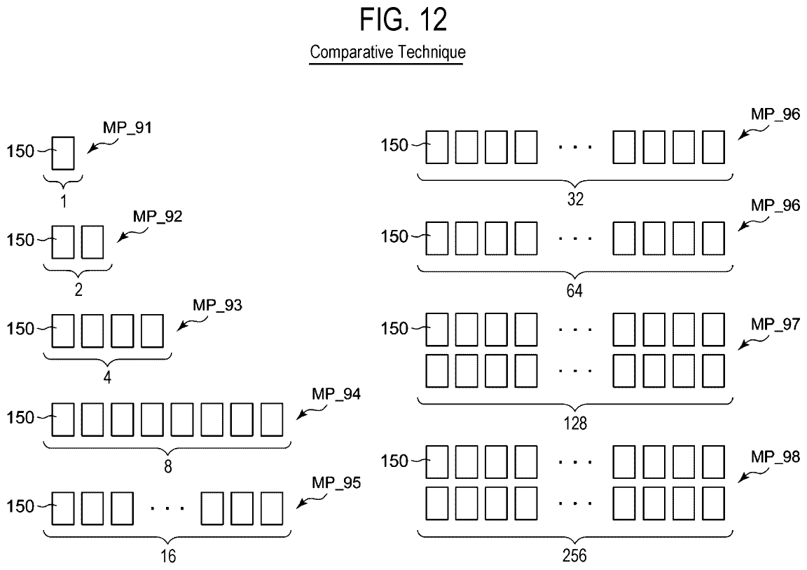

FIG. 12 is a diagram illustrating configurations of the transistors MP_91 to MP_99 included in the switching current source 932 according to the comparative technique. The transistors MP_91 to MP_99 according to the comparative technique are respectively constituted with MOS transistors 150 having a first gain. When the transistors MP_91 to MP_99 are designated as first to ninth transistors in this order, a γ-th (γ is an integer from 1 to 9) transistor is constituted with 2^{γ-1} MOS transistors 150.

By configuring the transistors MP_91 to MP_99 in this manner, drain currents I_{ON_91} to I_{ON_99} of the transistors MP_91 to MP_99 have binary-weighted magnitudes. Specifically, when the drain current I_{ON_91} when the transistor MP_91 is turned on is 1 mA, the drain currents of the transistors MP_92 to MP_99 in the turn-on state are I_{ON_92}=2 mA, I_{ON_93}=4 mA, I_{ON_94}=8 mA, I_{ON_95}=16 mA, I_{ON_96}=32 mA, I_{ON_97}=64 mA, I_{ON_98}=128 mA, and I_{ON_99}=256 mA, respectively. As a result, the range of the switching current I_{ON_9} becomes 1 mA to 511 mA.

Returning to FIG. 10, the control circuit 900 provided in the gate driver circuit 90 according to the comparative technique will be described. Unlike the control circuit 100 according to this embodiment, the control circuit 900 according to the comparative technique does not include the high-side selector 108a and the low-side selector 108b, but instead includes a logic circuit 902, a level shifter block 904a for the high-side driver 920a, and a level shifter block 904b for the low-side driver 920b.

The logic circuit 902 generates a control signal for controlling the high-side driver 920a and a control signal for controlling the low-side driver 920b based on the input signal S_{IN} and the sensor signal S_{SNS}. The following mainly describes a configuration of the control circuit 900 for controlling the switching current source 932 of the high-side driver 920a.

The control signal for controlling the high-side driver 920a includes a 9-bit first control signal S_{H_91} for individually controlling the on/off states of the transistors MP_91 to MP_99 of the switching current source 932. A bit (γ-1) (γ is an integer from 1 to 9) of the 9-bit first control signal S_{H_91} corresponds to the transistor MP_9y of the switching current source 932.

The level shifter block 904a level-shifts each bit of the first control signal S_{H_91} to generate a 9-bit second control signal S_{H_92}. The level shifter block 904a includes nine level shifters to level-shift the 9-bit second control signal S_{H_92}. Further, the level shifter block 904b may be configured in the same manner as the level shifter block 904a.

The second control signal S_{H_92} is transmitted to the high-side driver 920a. The on/off states of the transistors MP_91 to MP_99 of the switching current source 932 are controlled by the corresponding bits of the second control signal S_{H_92}.

An area of the first transistors MP_SL1 to MP_SL5 that constitute the first switching current source 132 and the second transistors MP_SH1 to MP_SH5 that constitute the second switching current source 134 according to this embodiment is smaller than that of the transistors MP_91 to MP_99 that constitute the switching current source 932 according to the comparative technique. This is because the number (62=31+31) of MOS transistors that constitute the first transistors MP_SL1 to MP_SL5 and the second transistors MP_SH1 to MP_SH5 according to this embodiment is smaller than the number (511) of MOS transistors that constitute the transistors MP_91 to MP_99 according to the comparative technique.

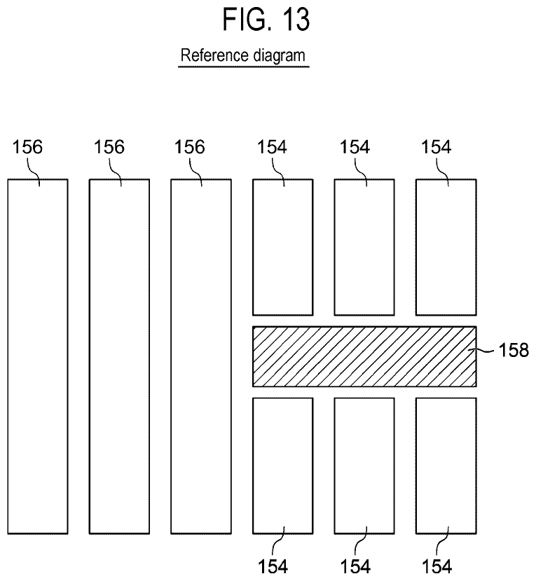

Referring to FIG. 13, how the area of transistors may be reduced by reducing the number of MOS transistors will be described. FIG. 13 is a reference diagram showing an example of a layout of MOS transistors 154 and 156 of two different sizes. FIG. 13 shows a layout of six relatively small MOS transistors 154 and six relatively large MOS transistors 156.

When arranging the plurality of MOS transistors 154, as shown in FIG. 13, a space 158 may be required between the MOS transistors 154. For example, the space 158 may be required to prevent the gates of the MOS transistors 154 from getting too close to each other. Therefore, the larger the number of MOS transistors 154, the more spaces 158 are required. As a result, the area required for the transistor layout becomes larger. In other words, the fewer MOS transistors there are, the smaller the area required for the transistor layout may be.

The first switching current source 132 and the second switching current source 134 according to this embodiment may be configured with fewer MOS transistors than the switching current source 932 according to the comparative technique, thereby reducing the layout area. Further, in the control circuit 100 according to this embodiment, the first switching current source 132 and the second switching current source 134 may be controlled with a total of six bits, including a five-bit first control signal S_{H_1} and a single-bit first mode signal S_{H_3}. In contrast, the control circuit 900 according to the comparative technique requires a nine-bit first control signal S_{H_91} to control the switching current source 932. Therefore, while the control circuit 100 according to this embodiment may level-shift the required signals with six level shifters (the control level shifters 104_1 to 104_5 and the mode level shifter 106), the control circuit 900 according to the comparative technique requires nine level shifters. In this way, with the gate driver circuit 10 according to this embodiment, it is possible to reduce the number of level shifters, thereby reducing a circuit area.

### Second Embodiment

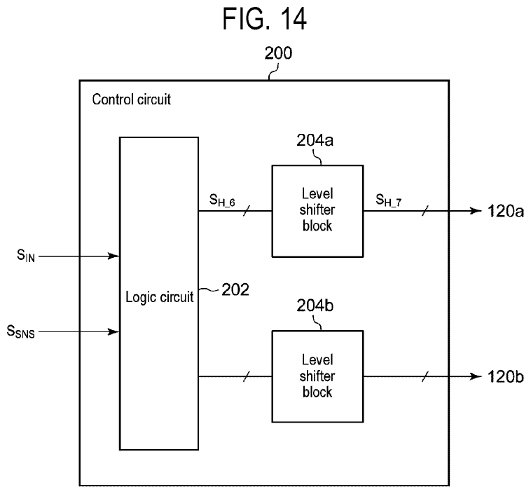

FIG. 14 is a block diagram of a control circuit 200 according to a second embodiment. The control circuit 200 according to the second embodiment may be provided in the switching circuit 1 or the gate driver circuit 10 according to the first embodiment, instead of the control circuit 100 according to the first embodiment. The control circuit 200 according to the second embodiment includes a logic circuit 202 and level shifter blocks 204a and 204b.

The logic circuit 202 generates a control signal for controlling the high-side driver 120a and a control signal for controlling the low-side driver 120b. The level shifter block 204a level-shifts the control signal for controlling the high-side driver 120a, and the level shifter block 204b level-shifts the control signal for controlling the low-side driver 120b.

The following describes the control circuit 200, focusing mainly on a configuration for controlling the first switching current source 132 and the second switching current source 134 of the turn-on circuit 130 of the high-side driver 120a. Further, the configuration to be described below may also be applied to a configuration for controlling the turn-off circuit 140 of the high-side driver 120a or the turn-on circuit and turn-off circuit of the low-side driver 120b.

The control signal for controlling the high-side driver 120a include a first control signal S_{H_6} for controlling the first switching current source 132 and the second switching current source 134 of the turn-on circuit 130. The first control signal S_{H_6} is a 10-bit signal, with each bit corresponding to a respective one of ten transistors (five first transistors MP_SL1 to MP_SL5 and five second transistors MP_SH1 to MP_SH5) that make up the first switching current source 132 and the second switching current source 134. Specifically, a bit (δ−1) of the first control signal S_{H_6} corresponds to the first transistor MP_SLδ (δ is an integer from 1 to 5) and the second transistor MP_SH (δ−5) (δ is an integer from 6 to 10).

The level shifter block 204a level-shifts each bit of the first control signal S_{H_6} to generate a 10-bit second control signal S_{H_7}. The second control signal S_{H_7} simultaneously and individually controls the on/off states of the first transistors MP_SL1 to MP_SL5 and the on/off states of the second transistors MP_SH1 to MP_SH5.

This configuration of the control circuit 200 may also achieve the effect of reducing the area of the first transistors MP_SL1 to MP_SL5 and the second transistors MP_SH1 to MP_SH5, in the same manner as the gate driver circuit 10 according to the first embodiment.

As described above, the range of the first switching current I_{ON_SL} and the range of the second switching current I_{ON_SH} may partially overlap with each other. When a desired current range is close to the overlapping range, an appropriate current may be easily achieved by switching the respective current amounts of the first switching current source 132 and the second switching current source 134, as in the control circuit 100 according to the first embodiment. Further, an appropriate turn-off current may also be achieved by performing similar control.

### Application Example

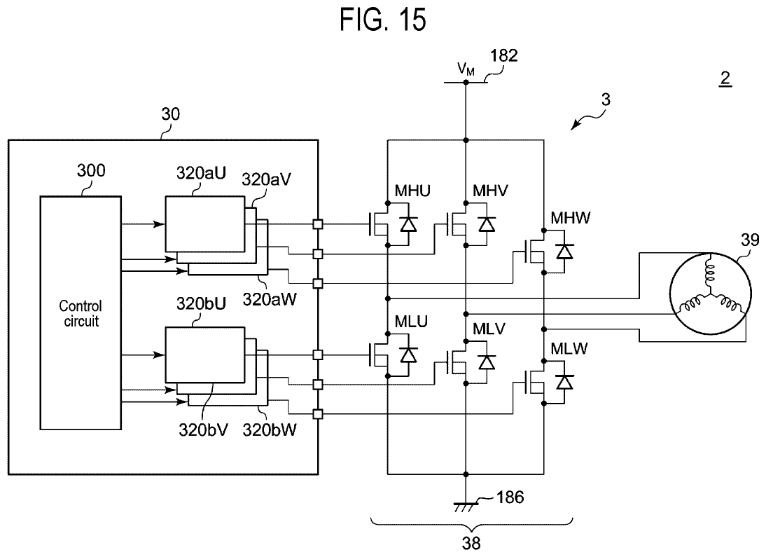

The switching circuit 1 according to the above-described embodiments may be applied to a motor drive circuit. FIG. 15 is a block diagram of a motor drive device 2 according to an application example. The motor drive device 2 includes a switching circuit 3 and a three-phase motor 39 as a load. The motor drive device 2 drives the three-phase motor 39 and controls its rotation state.

The switching circuit 3 includes a gate driver circuit 30 and a three-phase bridge circuit 38 (three-phase inverter). The three-phase bridge circuit 38 has U-phase, V-phase, and W-phase legs. The U-phase leg includes a first high-side transistor MHU and a first low-side transistor MLU. The V-phase leg includes a second high-side transistor MHV and a second low-side transistor MLV. The W-phase leg includes a third high-side transistor MHW and a third low-side transistor MLW.

The gate driver circuit 20 includes a control circuit 300, high-side drivers 320aU to 320aW, and low-side drivers 320bU to 320bW. The control circuit 300 generates control signals, which indicate the states of six arms that make up the three-phase bridge circuit 38, based on the state of the three-phase motor 39 which serves as the load. The high-side drivers 320aU to 320aW are configured with an architecture of the high-side driver 120a described above. The low-side drivers 320bU to 320bW are configured with an architecture of the low-side driver 120b described above.

Although an example in which the load is a three-phase motor has been described above, the load may also be a single-phase motor. In this case, a half-bridge circuit may be provided instead of the three-phase bridge circuit 38.

### (Supplements)

The embodiments according to the present disclosure have been described using specific terms, but this description is merely an example to aid understanding and does not limit the scope of the present disclosure or the claims, and the scope of the present disclosure is defined by the claims. Further, not only the above-described embodiments, but also embodiments, examples, and modifications not described herein are included in the scope of the present disclosure. For example, one or more elements of one embodiment may be combined with one or more elements of another embodiment.

### (First Modification)

The operation of the gate driver circuit 10 according to the first embodiment has been described with reference to FIG. 9 by taking an example in which the mode is switched during the second period T2. However, the present disclosure is not limited thereto, and the mode may be the same in the first period T1 and the third period T3. For example, the control circuit 100 may be in the first mode or the second mode during both the first period T1 and the third period T3. Further, an example in which the first base current source 136 is turned on and the second base current source 138 is turned off during the first period T1 to the fourth period T4 has been described with reference to FIG. 9, but the present disclosure is not limited thereto. The first base current source 136 may be turned off and the second base current source 138 may be turned on.

### (Second Modification)

In the above-described embodiments, an example has been mainly described in which two switching current sources (for example, the first switching current source 132 and the second switching current source 134) are constituted with MOS transistors with two types of gains. However, the present disclosure is not limited thereto. Three or more switching current sources may be constituted with MOS transistors with three or more types of gains.

### (Third Modification)

In the above-described embodiments, an example has been described in which the power transistors (for example, the high-side transistor MH and the low-side transistor MN) are constituted with N-channel MOS transistors. However, the present disclosure is not limited thereto. The power transistors may be constituted with P-channel MOS transistors.

### (Fourth Modification)

In the above-described embodiments, an example has been described in which the transistors used in the high-side driver 120a and the low-side driver 120b (for example, the first transistors MP_SL1 to MP_SL5 and the second transistors MP_SH1 to MP_SH5) are configured to operate in the saturation region. However, the present disclosure is not limited thereto. These transistors may be configured to operate in a linear region.

### (Supplementary Notes)

The technique disclosed in the present disclosure may be understood in one aspect as follows.

### (Item 1)

A gate driver circuit for driving a power transistor, comprising:
a turn-on circuit configured to source a turn-on current to a gate of the power transistor during a turn-on period of the power transistor;
a turn-off circuit configured to sink a turn-off current from the gate of the power transistor during a turn-off period of the power transistor; and
a control circuit configured to control the turn-on circuit and the turn-off circuit,
wherein the turn-on circuit or the turn-off circuit includes a current source circuit configured to be capable of switching an amount of the turn-on current or the turn-off current,
wherein the current source circuit includes a first switching current source and a second switching current source,
wherein the first switching current source includes a plurality of first transistors connected in parallel to each other, and is configured to source or sink a first switching current to or from the gate, the first switching current corresponding to a first transistor, which is turned on, among the plurality of first transistors,
wherein the second switching current source includes a plurality of second transistors connected in parallel each other, and is configured to source or sink a second switching current to or from the gate, the second switching current corresponding to a second transistor, which is turned on, among the plurality of second transistors,
wherein the first transistor is constituted with a MOS transistor having a first gain,
wherein the second transistor is constituted with a MOS transistor having a second gain greater than the first gain, and
wherein the control circuit individually controls on/off states of the plurality of first transistors or on/off states of the plurality of second transistors.

### (Item 2)

In the gate driver circuit of Item 1 above, each of the first transistor and the second transistor is configured to operate in a saturation region.

### (Item 3)

In the gate driver circuit of Item 1 or 2 above, the control circuit is configured to be capable of switching a mode between a first mode in which the on/off states of the plurality of first transistors are individually controlled, and a second mode in which the on/off states of the plurality of second transistors are individually controlled.

### (Item 4)

In the gate driver circuit of Item 3 above, a non-zero minimum value of the second switching current is between a non-zero minimum value of the first switching current and a maximum value of the first switching current, and
wherein a maximum value of the second switching current is higher than the maximum value of the first switching current.

### (Item 5)

In the gate driver circuit of Item 3 or 4 above, the control circuit generates a multi-bit control signal and a single-bit mode signal indicating a mode of the control circuit,
wherein each bit of the control signal is associated with a respective transistor of the plurality of first transistors and a respective transistor of the plurality of second transistors,
wherein, among the first transistor and the second transistor, the on/off state of one transistor in a mode indicated by the mode signal is switchable, and the other transistor is turned off, and
wherein, among the plurality of first transistors and the plurality of second transistors, the on/off states of the transistors in the switchable state are individually switched in response to the control signal.

### (Item 6)

The gate driver circuit of Item 5 above further includes: a plurality of control level shifters, a mode level shifter, and a selector,
wherein each of the plurality of control level shifters level-shifts a signal of a corresponding bit of the multi-bit control signal,
wherein the mode level shifter level-shifts the mode signal, and
wherein, based on the level-shifted control signal from the control level shifter and the level-shifted mode signal from the mode level shifter, the selector generates a gate signal for controlling the on/off state of one transistor among the first transistor and the second transistor in the mode indicated by the mode signal, and a gate signal for turning off the other transistor.

### (Item 7)

In the gate driver circuit of any one of Items 1 to 6 above, the current source circuit further includes a base current source configured to generate a constant amount of base current equal in direction to the first switching current and the second switching current.

### (Item 8)

In the gate driver circuit of Item 7 above, the control circuit turns on at least one of the plurality of first transistors and turns off all of the plurality of second transistors during a first period, turns off all of the plurality of first transistors and the plurality of second transistors during a second period following the first period, and turns off all of the plurality of first transistors and turns on at least one of the plurality of second transistors during a third period following the second period, and
wherein an amount of the second switching current during the third period is greater than an amount of the first switching current during the first period.

### (Item 9)

In the gate driver circuit of Item 7 or 8 above, the base current source includes a first base current source configured to generate a first base current, and a second base current source configured to generate a second base current,
wherein the first base current source includes a third transistor constituted with the MOS transistor having the first gain, and
wherein the second base current source includes a fourth transistor constituted with the MOS transistor having the second gain.

### (Item 10)

In the gate driver circuit of any one of Items 1 to 9 above, the control circuit simultaneously and individually controls the on/off states of the plurality of first transistors and the on/off states of the plurality of second transistors.

### (Item 11)

In the gate driver circuit of any one of Items 1 to 10 above, the MOS transistor constituting the second transistor is larger in size than the MOS transistor constituting the first transistor.

### (Item 12)

In the gate driver circuit of any one of Items 1 to 11 above, a number of the plurality of first transistors is m (m is an integer of 2 or greater), and the number of the plurality of second transistors is n (n is an integer of 2 or greater),
wherein an α-th (α is an integer from 1 to m) first transistor of the plurality of first transistors is constituted with 2^{α-1} MOS transistors having the first gain, and
wherein a β-th (β is an integer from 1 to n) second transistor of the plurality of second transistors is constituted with 2^{β-1} MOS transistors having the second gain.

### (Item 13)

A switching circuit includes:
a bridge circuit including a high-side transistor and a low-side transistor; and
the gate driver circuit of any one of Items 1 to 12, wherein the gate driver circuit is configured to drive the high-side transistor or the low-side transistor as a power transistor.

What is claimed is:

1. A gate driver circuit for driving a power transistor, comprising:
a turn-on circuit configured to source a turn-on current to a gate of the power transistor during a turn-on period of the power transistor;
a turn-off circuit configured to sink a turn-off current from the gate of the power transistor during a turn-off period of the power transistor; and
a control circuit configured to control the turn-on circuit and the turn-off circuit,
wherein the turn-on circuit or the turn-off circuit includes a current source circuit configured to be capable of switching an amount of the turn-on current or the turn-off current,
wherein the current source circuit includes a first switching current source and a second switching current source,
wherein the first switching current source includes a plurality of first transistors connected in parallel to each other, and is configured to source or sink a first switching current to or from the gate, the first switching current corresponding to a first transistor, which is turned on, among the plurality of first transistors,
wherein the second switching current source includes a plurality of second transistors connected in parallel each other, and is configured to source or sink a second switching current to or from the gate, the second switching current corresponding to a second transistor, which is turned on, among the plurality of second transistors,
wherein the first transistor is constituted with a MOS transistor having a first gain,
wherein the second transistor is constituted with a MOS transistor having a second gain greater than the first gain, and
wherein the control circuit individually controls on/off states of the plurality of first transistors or on/off states of the plurality of second transistors.

2. The gate driver circuit of claim 1, wherein each of the first transistor and the second transistor is configured to operate in a saturation region.

3. The gate driver circuit of claim 1, wherein the control circuit is configured to be capable of switching a mode between a first mode in which the on/off states of the plurality of first transistors are individually controlled, and a second mode in which the on/off states of the plurality of second transistors are individually controlled.

4. The gate driver circuit of claim 3, wherein a non-zero minimum value of the second switching current is between a non-zero minimum value of the first switching current and a maximum value of the first switching current, and
wherein a maximum value of the second switching current is higher than the maximum value of the first switching current.

5. The gate driver circuit of claim 3, wherein the control circuit generates a multi-bit control signal and a single-bit mode signal indicating a mode of the control circuit,
wherein each bit of the control signal is associated with a respective transistor of the plurality of first transistors and a respective transistor of the plurality of second transistors,
wherein, among the first transistor and the second transistor, the on/off state of one transistor in a mode indicated by the mode signal is switchable, and the other transistor is turned off, and
wherein, among the plurality of first transistors and the plurality of second transistors, the on/off states of the transistors in the switchable state are individually switched in response to the control signal.

6. The gate driver circuit of claim 5, further comprising: a plurality of control level shifters, a mode level shifter, and a selector,
wherein each of the plurality of control level shifters level-shifts a signal of a corresponding bit of the multi-bit control signal,
wherein the mode level shifter level-shifts the mode signal, and
wherein, based on the level-shifted control signal from the control level shifter and the level-shifted mode signal from the mode level shifter, the selector generates a gate signal for controlling the on/off state of one transistor among the first transistor and the second transistor in the mode indicated by the mode signal, and a gate signal for turning off the other transistor.

7. The gate driver circuit of claim 1, wherein the current source circuit further includes a base current source configured to generate a constant amount of base current equal in direction to the first switching current and the second switching current.

8. The gate driver circuit of claim 7, wherein the control circuit turns on at least one of the plurality of first transistors and turns off all of the plurality of second transistors during a first period, turns off all of the plurality of first transistors and the plurality of second transistors during a second period following the first period, and turns off all of the plurality of first transistors and turns on at least one of the plurality of second transistors during a third period following the second period, and
wherein an amount of the second switching current during the third period is greater than an amount of the first switching current during the first period.

9. The gate driver circuit of claim 7, wherein the base current source includes a first base current source configured to generate a first base current, and a second base current source configured to generate a second base current,
wherein the first base current source includes a third transistor constituted with the MOS transistor having the first gain, and
wherein the second base current source includes a fourth transistor constituted with the MOS transistor having the second gain.

10. The gate driver circuit of claim 1, wherein the control circuit simultaneously and individually controls the on/off states of the plurality of first transistors and the on/off states of the plurality of second transistors.

11. The gate driver circuit of claim 1, wherein the MOS transistor constituting the second transistor is larger in size than the MOS transistor constituting the first transistor.

12. The gate driver circuit of claim 1, wherein a number of the plurality of first transistors is m (m is an integer of 2 or greater), and a number of the plurality of second transistors is n (n is an integer of 2 or greater),
wherein an α-th (α is an integer from 1 to m) first transistor of the plurality of first transistors is constituted with 2^{α-1} MOS transistors having the first gain, and
wherein a β-th (β is an integer from 1 to n) second transistor of the plurality of second transistors is constituted with 2^{β-1} MOS transistors having the second gain.

13. A switching circuit comprising:
a bridge circuit including a high-side transistor and a low-side transistor; and
the gate driver circuit of claim 1,
wherein the gate driver circuit is configured to drive the high-side transistor or the low-side transistor as a power transistor.
